(19) United States
(12) Patent Application Publication
(10) Pub. No.: US 2008/0245413 A1
(43) Pub. Date: Oct. 9, 2008

(54) SELF ASSEMBLED PHOTOVOLTAIC DEVICES

(76) Inventors: Hang Ruan, Christiansburg, VA (US); Yuhong Kang, Christiansburg, VA (US); Jennifer Hoys Lalli, Blacksburg, VA (US); Richard Otto Claus, Eggleston, VA (US)

Correspondence Address: SHERR & VAUGHN, PLLC, 620 HERNDON PARKWAY, SUITE 200, HERNDON, VA, 20170, US

(21) Appl. No.: 12/062,936

(22) Filed: Apr. 4, 2008

Related U.S. Application Data
(60) Provisional application No. 60/884,543, filed on Apr. 4, 2007.

(51) Int. Cl. H01L 31/04; H01L 31/028; H01L 31/0296; H01L 31/0304; H01L 31/032

(52) U.S. Cl. 136/260; 136/252; 136/261; 136/264; 136/265; 136/262; 977/774

(57) ABSTRACT

An apparatus (and a method of making the apparatus) that includes a first electrode, self-assembled photovoltaic layer(s) formed over the first electrode, and a second electrode formed over the self-assembled photovoltaic layer(s). The self-assembled photovoltaic layer(s) may be flexible (e.g. include polymer material and quantum dots). The self-assembled photovoltaic layer(s) may be formed at approximately room temperature.

The present application claims priority to U.S. Provisional Patent Application No. 60/884,543 (filed Apr. 4, 2007), which is hereby incorporated by reference in its entirety.

### BACKGROUND

Photovoltaics is a technology that may convert light directly into electricity. Due to the growing need for solar energy, the manufacture of solar cells and solar photovoltaic array has expanded over time. One example application of photovoltaics is generation of solar power by using solar cells packaged in photovoltaic modules. Photovoltaic modules may be electrically connected in solar photovoltaic arrays to convert energy from the sun into electricity. To explain the photovoltaic solar panel more simply, photons from sunlight knock electrons into a higher state of energy, creating electricity.

Solar cells produce direct current electricity from light, which can be used to power equipment or to recharge a battery. Example applications of photovoltaics ranges from powering orbiting satellites (or other spacecraft) to powering pocket calculators. Photovoltaic modules may also be used for grid connected power generation. Photovoltaic may be also be used in off-grid power generation for remote dwellings, roadside emergency telephones, remote sensing, and cathodic protection of pipelines.

Rigid photovoltaic cells may require protection from the environment (e.g. glass protective covers). When more power is required than a single cell can deliver, cells may be electrically connected together to form photovoltaic modules, or solar panels. A single module may be enough to power an emergency telephone, but for a house or a power plant the modules must be arranged in relatively large arrays. Due to the relatively high costs of manufacturing many types of solar cells (e.g. including photovoltaic cells), solar power may be uncompetitive for supplying grid electricity in many environments.

Accordingly, there may be practical limitations to the implementation of many types of photovoltaic devices because manufacturing costs are cost prohibitive. For example, because many types of photovoltaic devices are rigid (e.g. not flexible), the packaging of the photovoltaic devices (e.g. incorporation of glass protective cover) may incur significant expenses. As another example, many types of photovoltaic devices need to be manufactured in high temperature and/or high pressure conditions, which creates complications that increase the manufacturing costs.

### SUMMARY

Embodiments relate to an apparatus (and a method of making the apparatus) that includes a first electrode, self-assembled photovoltaic layer(s) formed over the first electrode, and a second electrode formed over the self-assembled photovoltaic layer(s). In embodiments, the self-assembled photovoltaic layer(s) is flexible (e.g. include polymer material and quantum dots). The self-assembled photovoltaic layer(s) may be formed at approximately room temperature.

Accordingly, in embodiments, self-assembled photovoltaic devices (e.g. solar panels) may be manufactured at a relatively low price. For example, because the self-assembled photovoltaic devices are flexible, packaging costs and/or incorporation into structures may be relatively easily accomplished, thus minimizing manufacturing costs. Further, since self-assembled photovoltaic devices may be manufactured at room temperatures, manufacturing processes may be relatively simple, thus minimizing manufacturing costs.

### DRAWINGS

Example FIG. 1 illustrates a photovoltaic device including a first electrode, at least one self-assembled photovoltaic layer, and a second electrode, in accordance with embodiments.

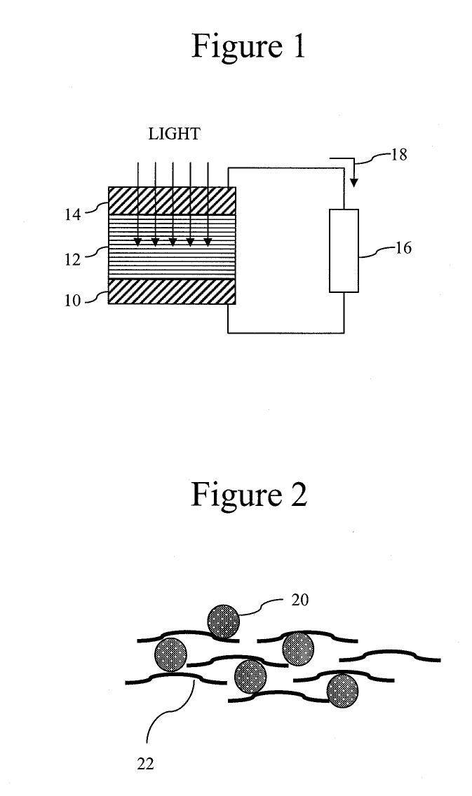

Example FIG. 2 illustrates a relationship between linking agent material and quantum dots in a self-assembled photovoltaic layer, in accordance with embodiments.

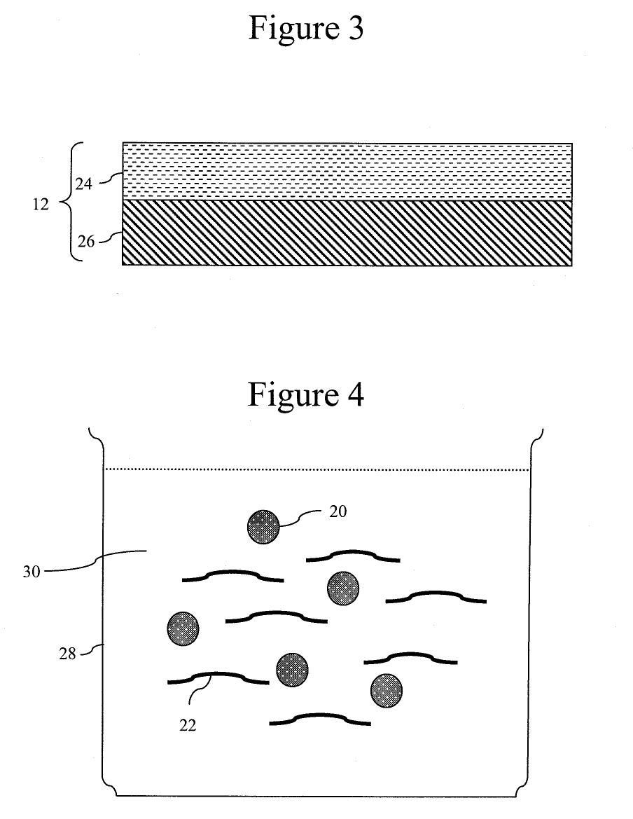

Example FIG. 3 illustrates multiple self-assembled photovoltaic layers, in accordance with embodiments.

Example FIG. 4 illustrates linking agent material and quantum dots dispersed in liquid, in accordance with embodiments.

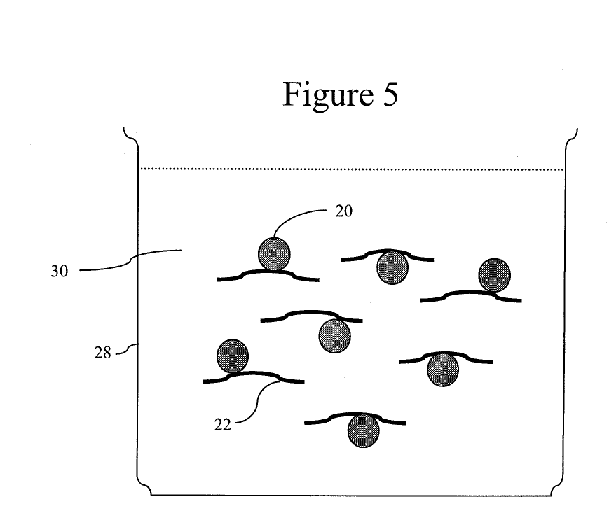

Example FIG. 5 illustrates bonded linking agent material and quantum dots dispersed in liquid prior to being formed into a photovoltaic device, in accordance with embodiments.

### DESCRIPTION

Example FIG. 1 illustrates a photovoltaic device including a first electrode 10, self-assembled photovoltaic layer(s) 12, and a second electrode 14, in accordance with embodiments. Light may be absorbed by the self-assembled photovoltaic layer(s) 12 and cause a current 18 to flow to load 16. Only first electrode 10, self-assembled photovoltaic layer(s) 12, and second electrode 14 are illustrated as part of a photovoltaic device for simplicity of illustration and other peripheral and integrated components may also be included. Self-assembled photovoltaic layer(s) 12 may include quantum materials (e.g. quantum dots) that generate electrons and/or holes when they absorb light. These generated electrons and/or hole may result in an electrical current 18 and/or voltage potential if electrically connected to a load 16. Generally, quantum materials are materials that generate electrons and/or hole upon absorption of light. The absorption of light may cause quantum materials to be excited to a higher energy band, thus releasing electrical energy (e.g. current and/or voltage potential) as a byproduct of quantum conversion.

In embodiments, self-assembled photovoltaic layer(s) 12 include layers that are formed by self-assembly. U.S. patent application Ser. No. 10/774,683 (filed Feb. 10, 2004 and titled “RAPIDLY SELF-ASSEMBLED THIN FILMS AND FUNCTIONAL DECALS”) is hereby incorporated by reference in its entirety. U.S. patent application Ser. No. 10/774,683 discloses self-assembly of linking agent material and/or nano-particles, in accordance with embodiments. Through self assembly, linking agent material (e.g. polymers) and/or nano-particles may be substantially uniformally and/or spatially dispersed during deposition to form a self assembled film, in accordance with embodiments. The self assembly of linking agent material and/or nano-particles may utilize electrostatic and/or covalent bonding of the linking agent material and/or individual nano-particles to a host layer or underlying layer. A host layer or underlying layer may be polarized in order to allow for the linking agent material and/or nano-particles to bond to the host layer or underlying layer, in accordance with embodiments.

U.S. patent application Ser. No. 10/774,683 (which is incorporated by reference above) discloses examples of linking agent materials. Linking agent material layer(s) may include polymer material. In embodiments, the polymer material may include poly(urethane), poly(etherurethane), poly(esterurethane), poly(urethane)-co-(siloxane), poly(dimethyl-co-methylhydrido-co-3-cyanopropyl, methyl) siloxane, and/or other similar materials. Linking agent material layer(s) may include materials that are polarized, in order for bonding with nano-particles and/or other (e.g. subsequent) linking agent material layer(s), in accordance with embodiments. In embodiments, linking agent materials may be conductive and/or semiconductive materials. In embodiments, linking agent material layer(s) may include a flexible material, an elastic material, and/or an elastomeric polymer.

Example FIG. 2 illustrates a relationship between a linking agent material 22 and quantum dots 20 in a self-assembled photovoltaic layer (e.g. self-assembled photovoltaic layer 12), in accordance with embodiments. Quantum dots 20 may be integrated into a self-assembled photovoltaic layer 12 by being bonded to linking agent material 22. In embodiments, quantum dots 20 may be nanocrystal quantum dots. Other photovoltaic materials aside from quantum dots may be implemented, in accordance with embodiments.

Although linking agent material 22 may not have photovoltaic properties, linking agent material may physically support the quantum dots 20. Linking agent material 22 may have properties that allow for self-assembly. Accordingly, quantum dots 20 bonded to linking agent material 22 may be effectively self-assembled. In embodiments, self-assembly may allow the quantum dots 20 to be dispersed in a photovoltaic layer in a relatively uniform and relatively predictable manner. Such uniformity and/or predictability allows for a photovoltaic device to be fabricated having predetermined properties and/or maximum efficiency.

In embodiments, linking agent material 22 may be a flexible material. Since quantum dots 20 may be substantially smaller in size (e.g. 10-50 nanometers) than linking agent material 22 (e.g. 200-500 nanometers), quantum dots may have a minimal effect on the overall structural attributes of a self-assembled layer. For example, the structural attributes (e.g. flexibility) of a self-assembled photovoltaic layer having a material structure illustrated in example FIG. 2 may be substantially dominated by the structural attributes (e.g. flexibility) of the linking agent material. In embodiments, a self-assembled photovoltaic layer may be relatively flexible. Flexibility of a photovoltaic layer may minimize costs of manufacturing a photovoltaic device and/or allow for more diverse applications that require flexible films, in accordance with embodiments.

In embodiments, linking agent material may include at least one of poly[2-methoxy-5-(2-ethylhexyloxy)-1,4-phenylenevinylene], poly (3-hexylthiophene), poly(ethylene dioxythiophene) polystyrene sulfonic acid, polydimethyldidodecylammonia, and polyethyleneimine. In embodiments, linking agent material may include a conductive and/or semiconductive material. A conductive and/or semiconductive material in the linking agent material may allow for electrons generated by the quantum materials (in response to light) to efficiently move out of a photovoltaic area to electrodes, in accordance with embodiments. Electron efficiency may maximize the overall efficiency of a photovoltaic device.

In embodiments, self assembly of photovoltaic layers may be performed at room temperature (and room pressure). The ability to form photovoltaic layers at room temperature may minimize manufacturing complications, which may reduce overall costs.

Example FIG. 3 illustrates multiple self-assembled photovoltaic layers 24, 26 which may be included in self-assembled photovoltaic layers 12, in accordance with embodiments. Only two self-assembled photovoltaic layers are illustrated in FIG. 3 for simplification of illustration and any number of layers may be included. In embodiments, a photovoltaic layer may include both self-assembled layers and non-self-assembled layers. Different self-assembled layers may have different photovoltaic attributes. In embodiments, first self-assembled photovoltaic layer 24 may include a first type of quantum dots and second self-assembled photovoltaic layer 26 may include a second type of quantum dots. For example, a first type of quantum dots may be responsive to a first waveband of light to generate electrons, while a second type of quantum dots may be responsive to a second (different) waveband of light to generate electrons. Accordingly, self-assembled photovoltaic layers 12 may be tailored to have specific functionalities (e.g. a tailored responsiveness to a predetermined overall waveband of light). In embodiments, different self-assembled photovoltaic layer may have substantially the same type of quantum dots.

In embodiments, different types of quantum dots may have different diameters. The diameter of a quantum dot may contribute to the waveband of light to which a quantum dot is responds to generate electrons. In embodiments, the quantum dots include at least one of Si, Ge, TeCdHg, CdS, CdSe, CdTe, InP, InAs, ZnS, ZnSe, ZnTe, HgTe, GaN, GaP, GaAs, GaSb, InSb, PbTe, AlAs, AlSb, PbSe, and PbS. However, other materials for quantum dots may be implemented, in accordance with embodiments.

Example FIG. 4 illustrates linking agent material 22 and quantum dots 20 dispersed in liquid 30, in accordance with embodiments. In a self-assembly formation process, liquid 30 may be used as a delivery medium (e.g. by immersion, spraying, and other methods). Prior to deposition of a self-assembled photovoltaic layer 12, quantum dots 20 and linking agent material 22 may be dispersed in liquid 30, as illustrated in FIG. 4. Through agitation and/or the passage of time, quantum dots 20 and linking agent material 22 may bond to each other, as illustrated in Example FIG. 5. After bonding of quantum dots 20 and linking agent material 22, linking agent material 22 with quantum dots 20 attached may be self-assembled to form a self-assembled photovoltaic layer 12, in accordance with embodiments.

Example FIGS. 1-5 are simplified illustrates and are not to scale. Intermediate and/or additional layers and materials may be appreciated that are not illustrated in example FIGS. 1-5

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a first electrode;
at least one self-assembled photovoltaic layer formed over the first electrode; and
a second electrode formed over said at least one self-assembled photovoltaic layer.

2. The apparatus of claim 1, wherein said at least one self-assembled photovoltaic layer is flexible.

3. The apparatus of claim 1, wherein at least one of said at least one self-assembled photovoltaic layer comprises quantum dots.

4. The apparatus of claim 3, wherein the quantum dots are nanocrystal quantum dots.

5. The apparatus of claim 3, wherein said at least one of said at least one self-assembled photovoltaic layer comprises polymer material.

6. The apparatus of claim 5, wherein said polymer material comprises at least one of:
poly[2-methoxy-5-(2-ethylhexyloxy)-1,4-phenylenevinylene];
poly (3-hexylthiophene);
poly(ethylene dioxythiophene) polystyrene sulfonic acid;
polydimethyldidodecylammonia; and
polyethyleneimine.

7. The apparatus of claim 5, wherein the quantum dots are bonded to the polymer material.

8. The apparatus of claim 7, wherein the quantum dots are bonded to the polymer material before said at least one self-assembled photovoltaic layer is formed over the first electrode.

9. The apparatus of claim 8, wherein the quantum dots are bonded to the polymer material when both the polymer material and the quantum dots are dispersed in a liquid.

10. The apparatus of claim 9, wherein the liquid is a delivery medium of said at least one self-assembled photovoltaic layer during self-assembly deposition.

11. The apparatus of claim 5, wherein the polymer material comprises at least one of a semiconductor polymer material and a conductive polymer material.

12. The apparatus of claim 3, wherein said at least one self-assembled photovoltaic layer comprises a first self-assembled photovoltaic layer and a second self-assembled photovoltaic layer.

13. The apparatus of claim 12, wherein the first self-assembled photovoltaic layer and the second self-assembled photovoltaic layer comprises substantially the same type of quantum dots.

14. The apparatus of claim 12, wherein the first self-assembled photovoltaic layer and the second self-assembled photovoltaic layer comprise substantially different types of quantum dots.

15. The apparatus of claim 14, wherein the first self-assembled photovoltaic layer comprises a first type of quantum dots having a first diameter and the second self-assembled photovoltaic layer comprises a second type of quantum dots having a second diameter.

16. The apparatus of claim 14, wherein:
the first self-assembled photovoltaic layer comprises a first type of quantum dots that are responsive to a first waveband of light to generate at least one of electrons and holes;
the second self-assembled photovoltaic layer comprises a second type of quantum dots that are responsive to a second waveband of light to generate at least one of electrons and holes; and
the first waveband and the second waveband are different wavebands.

17. The apparatus of claim 3, wherein the quantum dots comprise at least one of:
Si;
Ge;
TeCdHg;
CdS;
CdSe;
CdTe;
InP;
InAs;
ZnS;
ZnSe;
ZnTe;
HgTe;
GaN;
GaP;
GaAs;
GaSb;
InSb;
PbTe;
AlAs;
AlSb;
PbSe; and
PbS.

18. The apparatus of claim 1, wherein said at least one self-assembled photovoltaic layer is formed at approximately room temperature.

19. A method comprising:
forming a first electrode;
forming at least one photovoltaic layer over the first electrode by self-assembly; and
forming a second electrode over said at least one photovoltaic layer.

20. The method of claim 19, wherein at least one of said at least one photovoltaic layer comprises quantum dots.
